(19) United States
(12) Patent Application Publication
(10) Pub. No.: US 2010/0008045 A1
(43) Pub. Date: Jan. 14, 2010

(54) HEAT SINK

(75) Inventor: HONG-BO XU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY(ShenZhen) Co., LTD, Shenzhen City (CN); HON HAI PRECISION INDUSTRY CO., LTD., Tu-Cheng (TW)

(21) Appl. No.: 12/169,642

(22) Filed: Jul. 9, 2008

(51) Int. Cl. H05K 7/20

(52) U.S. Cl. 361/709

(57) ABSTRACT

A heat sink used to dissipate a heat source includes a heat-dissipating portion and a heat-conducting portion secured into the heat-dissipating portion. The heat-dissipating portion includes a base and fins extending from the base. The base defines a threaded hole in a bottom thereof. The heat-conducting portion includes a substrate for contacting with the heat source and a threaded portion extending from the substrate. The threaded portion of the heat-conducting portion is positioned in the base of the heat-dissipating portion and secured in the base of the heat-dissipating portion by the threaded portion engaging in the threaded hole of the base of the heat-dissipating portion.

### BACKGROUND OF THE INVENTION

1. Field of the Invention

The present invention relates to a heat sink, and more particularly to a heat sink for removing heat from an electronic package and dissipating the heat to ambient air. The heat sink consists of two components made of different materials and threadedly connected together.

2. Description of Related Art

A heat sink is usually placed in thermal contact with an electronic package, such as a central processing unit (CPU), to transfer heat through conduction away from the electronic package, thus preventing over-heating of the electronic package.

Generally, a heat sink comprises a base contacting the electronic package for absorbing heat from the electronic package, and a plurality of fins extending perpendicularly from the base to dissipate the heat deriving from the electronic package. To achieve an excellent heat-dissipating efficiency of the heat sink, a heat-conducting base made of copper is usually used to be attached to a bottom surface of the base of the heat sink to directly absorb the heat from the electronic package and then quickly conduct the heat to the base and fins of the heat sink. By this design, the heat-dissipating efficiency of the heat sink is greatly improved. However, how to easily and firmly fix the heat-conducting base to the base of the heat sink is a problem.

Therefore, an improved heat sink, which overcomes the above-mentioned problem is desired.

### SUMMARY OF THE INVENTION

The present invention relates to a heat sink used to dissipate heat from a heat source, for example a CPU. According to a preferred embodiment of the present invention, the heat sink includes a heat-dissipating portion and a heat-conducting portion secured into the heat-dissipating portion. The heat-dissipating portion is made by aluminum extrusion and the heat-conducting portion is formed by machining a copper block. The heat-dissipating portion includes a base and fins extending from the base. The base defines a threaded hole in a bottom thereof. The heat-conducting portion includes a substrate for contacting with the heat source and a threaded portion extending upwardly from the substrate. The threaded portion of the heat-conducting portion is positioned in the base of the heat-dissipating portion and secured in the base of the heat-dissipating portion by the threaded portion engaging in the threaded hole of the base of the heat-dissipating portion. The heat-conducting portion is threadedly secured into the heat-dissipating portion, which is very advantageous in view of assembly of the heat sink. A top surface of the threaded portion engages with the bottom of the base over the threaded hole. A bore is defined in the base of the heat dissipating-dissipation portion and communicates the threaded hole and a top of the base. Heat-conducting grease is spread on the top surface of the threaded portion.

Other advantages and novel features will become more apparent from the following detailed description of preferred embodiments when taken in conjunction with the accompanying drawings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a heat sink in accordance with a preferred embodiment of the present invention, wherein the heat sink is turned 90 degrees from its normally used position.

FIG. 2 is an exploded view of FIG. 1.

FIG. 3 is a cross-sectional view of the heat sink taken along line III-III in FIG. 1.

FIG. 4 is an enlarged view of a circled portion IV of the heat sink in FIG. 3.

### DETAILED DESCRIPTION OF THE INVENTION

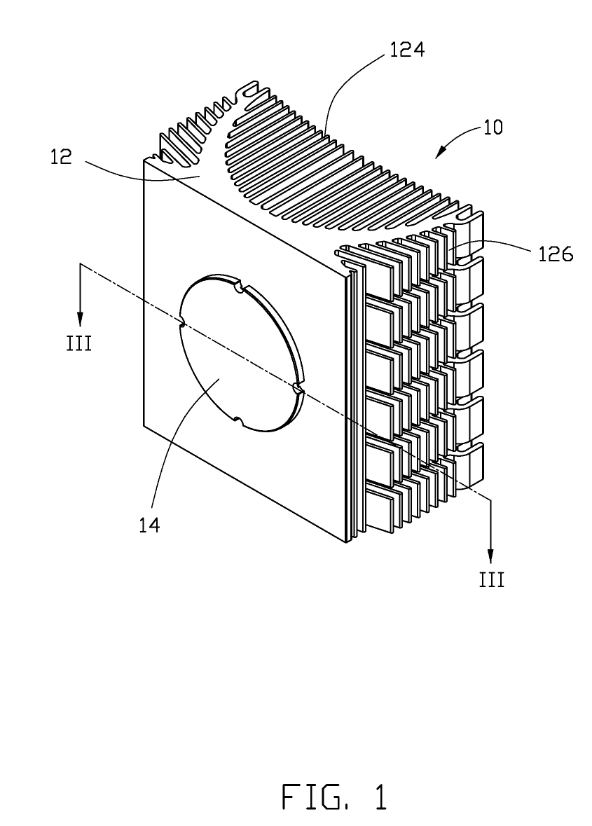

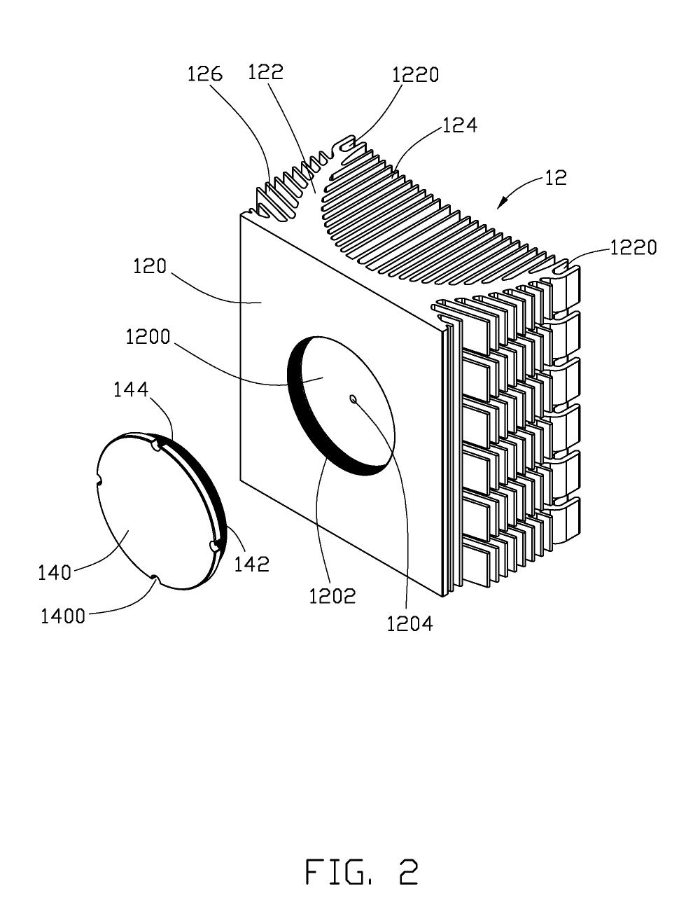

Referring to FIGS. 1-4, a heat sink in accordance with a preferred embodiment of the present invention is illustrated. The heat sink is used to remove heat from a heat source (not shown), such as a Central Processing Unit, a chip set, etc.

The heat sink 10 comprises a heat-dissipating portion 12 integrally formed by aluminum extrusion and a heat-conducting portion 14 received in the heat-dissipating portion 12 and formed by machining a copper block. The heat-conducting portion 14 is used to directly contact the heat source and absorb heat generated by the heat source.

The heat-dissipating portion 12 comprises a flat rectangular base 120 having a flat bottom surface and a pair of wings 122 integrally extending from a top surface of the base 120. A circular threaded hole 1200 is defined in a central portion of the bottom surface of the base 120. An internal thread 1202 is defined in an inner circumference of the base 20 surrounding the threaded hole 1200. A bore 1204 is defined in a center the base 120 and communicates a center of the threaded hole 1200 with the top surface of the base 120. The bore 1204 is communicated with ambient air, thereby facilitating removal of redundant heat-conducting grease in the threaded hole 1200 during assembling the heat-conducting portion 14 into the threaded hole 1200.

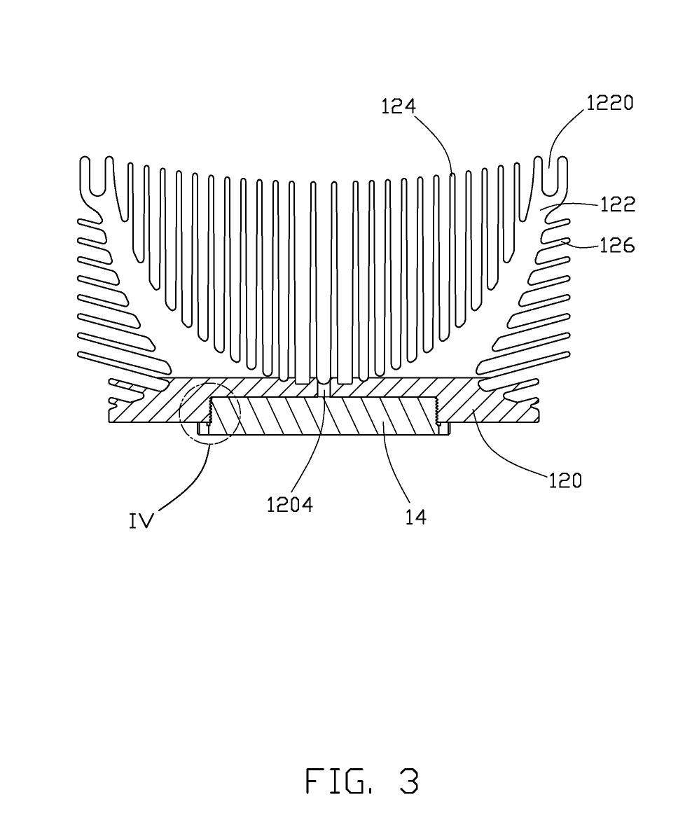

The wings 122 are respectively extend upwardly and outwardly from the top surface of the base 120 to render the wings 122 to have a substantially arc-shaped profile in the preferred embodiment. Although not shown in this embodiment, the wings 122 can also be rendered with a substantially V-shaped profile. Each wing 122 defines an elongated slot 1220 at a distal end thereof. The slot 1220 extends from a front side of the heat sink 10 to a rear side of the heat sink 10 as shown in FIG. 3. The slots 1220 facilitate to mount a fan (not shown) on a top of the heat sink 10, for example, by extending screws (not shown) through the fan to engage in the slots 1220.

As shown in FIG. 3, a plurality of vertical fins 124 and a plurality of lateral fins 126 extend from the wings 122 of the heat-dissipating portion 12, which are used to dissipate heat generated by the heat source to ambient air. The vertical fins 124 are extended upwardly from an upper side of the wings 122, and located between the wings 122. The vertical fins 124 are parallelly arranged from a left side to a right side of the heat sink 10. Top terminations of the vertical fins 124 corporately define a surface which is slightly concave toward a center of the heat sink 10. Some of the lateral fins 126 are extended outwardly from lateral sides of the base 120, and located between the base 120 and the wings 122. The lateral fins 126 are angled with the vertical fins 124 in the preferred embodiment.

A plurality of vertical channels (not labeled) for air flowing from a top toward a bottom of the heat-dissipating portion 12 are defined between the vertical fins 124. A plurality of channels (not labeled) for air flowing in a substantially horizontal direction are defined between the lateral fins 126.

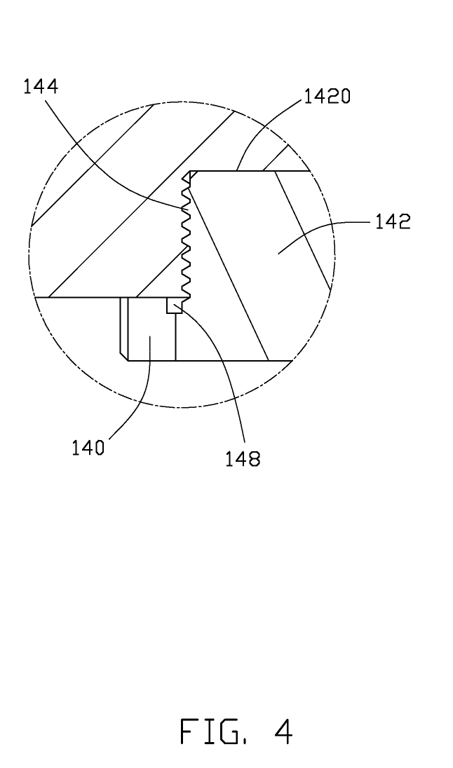

The heat-conducting portion 14 is made of copper and has a disc-shaped substrate 140 and a core-shaped threaded portion 142 extending upwardly from a center of the substrate 140. The substrate 140 has a flat bottom surface (not labeled) to directly contact the heat source and absorb the heat from the heat source. An external thread 144 is defined in an outer circumferential surface of the threaded portion 142. The external thread 144 is located and configured corresponding to the internal thread 1202 in the base 120 of the heat-dissipating portion 12 for screwing in the internal thread 1202 so as to secure the heat-conducting portion 14 to the heat-dissipating portion 12. The threaded portion 142 needs to be received in the threaded hole 1200 of the base 120, so the threaded portion 142 has a height similar to a depth of the threaded hole 1200 of the base 120 and an outer diameter similar to an inner diameter of the threaded hole 1200 of the base 120. Four cutouts 1400 are symmetrically recessed in a circumferential edge of the substrate 140, for facilitating a tool to engage with the substrate 140 to rotate the heat-conducting portion 14 into/away from the threaded hole 1200. As shown in FIG. 4, an annular groove 148 is defined in a top surface of the substrate 140 near a bottom of the threaded portion 142, thereby vacating a space for enabling a tool to easily form the external thread 144 in the threaded portion 142.

In assembly of the heat sink 10, the threaded portion 142 of the heat-conducting portion 14 is positioned in the threaded hole 1200 of the base 120 of the heat-dissipating portion 12 and is secured to the base 120 of the heat-dissipating portion 12 by the external thread 144 in the threaded portion 142 of the heat-conducting portion 14 screwing in the internal thread 1202 in the base 120 of the heat-dissipating portion 12. At this fixed position, the top surface 1420 of the threaded portion 142 of the heat-conducting portion 14 tightly abuts against the bottom surface of the base 120 over the threaded hole 1200, the external thread 144 securely, threadedly engages with the internal thread 1202 and the top surface of the substrate 140 tightly abut against the bottom surface of the base 120 around the threaded hole 1200. Thus, the heat-conducting portion 14 is firmly, screwedly connected to the base 120 of the heat-dissipating portion 12 and has an intimate thermal connection therewith. Before the assembly, heat-conducting grease is spread on the top surface 1420 of the threaded portion 142 to fill an air gap between the base 120 and the top surface 1420 after the assembly.

In use, the substrate 140 of the heat-conducting portion 14 directly contacting with the heat source absorbs the heat from the heat source, and then directly transfer the heat to the base 120 of the heat-dissipating portion 12, whereby the heat can be dissipated into ambient air via the fins 124, 126 of the heat-dissipating portion 12.

In comparison with the related art, the heat-conducting portion 14 is threadedly secured into the heat-dissipating portion 12, which is very advantageous in view of assembly of the heat sink 10. Moreover, an arrangement of the external thread 144 in the threaded portion 142 and the internal thread 1202 in the threaded hole 1200 together provides a large contacting surface between the heat-conducting portion 14 and the heat-dissipating portion 12 available to facilitate heat dissipation of the heat sink 10.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat sink for dissipating heat from a heat source, comprising:
a heat-dissipating portion comprising a base and a plurality of fins extending from a top surface of the base, the heat-dissipating portion being made of a first metal; and
a heat-conducting portion comprising a substrate and a threaded portion extending upwardly from the substrate, the substrate being adapted for contacting with the heat source, the heat-conducting portion being made of a second metal different from the first metal;
wherein the threaded portion of the heat-conducting portion is positioned in the base of the heat-dissipating portion and secured in the base of the heat-dissipating portion by the threaded portion engaging in the base of the heat-dissipating portion.

2. The heat sink as claimed in claim 1, wherein the base defines a threaded hole in a bottom thereof and the threaded portion of the heat-conducting portion is secured in the threaded hole of the base.

3. The heat sink as claimed in claim 2, wherein the base defines an internal thread in a circumference thereof surrounding the threaded hole and the threaded portion is secured to the internal thread.

4. The heat sink as claimed in claim 3, wherein the threaded portion comprises an external thread in a circumference of thereof, the external thread threadedly engaging with the internal thread of the threaded hole of the base.

5. The heat sink as claimed in claim 4, wherein the base of the heat-dissipating portion has a pair of wings integrally formed therefrom, the wings being substantially arc-shaped.

6. The heat sink as claimed in claim 5, wherein the fins comprises a plurality of vertical fins formed on an upper side of the wings and located between the wings.

7. The heat sink as claimed in claim 6, wherein the wings each define a slot at a distal end thereof adapted for insertion of a screw to mount a fan on the heat sink.

8. The heat sink as claimed in claim 6, wherein the fins comprises a plurality of lateral fins extended outwardly from lateral sides of the wings.

9. The heat sink as claimed in claim 1, wherein the substrate defines a plurality of cutouts recessed in an edge thereof, adapted for receiving a tool.

10. The heat sink as claimed in claim 2, wherein the base of the heat-dissipating portion defines a bore communicating the threaded hole and the top surface of the base.

11. The heat sink as claimed in claim 10, where a top surface of the threaded portion is spread with heat-conducting grease and engages the bottom of the base over the threaded hole.

12. The heat sink as claimed in claim 11, where a top surface of the substrate engages the bottom of the base around the threaded hole.

13. The heat sink as claimed in claim 12, wherein the heat-dissipating portion is made of aluminum and the heat-conducting portion is made of copper.

14. A heat sink for dissipating heat generated by a heat-generating electronic component, comprising:
a heat-dissipating portion made of aluminum extrusion, comprising a base having a top from which a plurality of fins extends and a bottom in which a threaded hole is defined;
a heat-contacting portion made of copper and adapted for contacting with the electronic component, having a substrate and a threaded portion extending upwardly from a center of the substrate; wherein
the threaded portion threadedly engages in the threaded hole, a top surface of the threaded portion being applied with heat-conducting grease and engaging with the bottom of the base over the threaded hole, a top surface of the substrate engaging the bottom of the base around the threaded hole, a bore being defined in the base and communicating the threaded hole with the top of the base.
